(19) United States
(12) Patent Application Publication
(10) Pub. No.: US 2017/0110611 A1
(43) Pub. Date: Apr. 20, 2017

(54) MULTIPLE-JUNCTION PHOTOVOLTAIC CELL BASED ON ANTIMONIDE MATERIALS

(71) Applicants: UNIVERSITE DE MONTPELLIER, Montpellier (FR); CENTRE NATIONAL DE LA RECHERCHE SCIENTIFIQUE, Paris (FR)

(72) Inventors: Yvan CUMINAL, Saint-Drezery (FR); Emmanuel GIUDICELLI, Montpellier (FR); Frédéric MARTINEZ, Saint-Drezery (FR)

(21) Appl. No.: 15/312,570

(22) PCT Filed: May 20, 2015
(86) PCT No.: PCT/EP2015/061160

§ 371 Date: Dec. 22, 2016

(30) Foreign Application Priority Data
May 20, 2014 (EP) 14305748.7

(51) Int. Cl. H01L 31/047; H01L 31/18; H01L 31/0304

(52) U.S. Cl. CPC H01L 31/047; H01L 31/03046; H01L 31/03042; H01L 31/1844

(57) ABSTRACT

A photovoltaic cell is provided that can be used under high levels of solar concentration (≧1000 suns). The present cell includes at least one junction produced on a substrate based on gallium antimonide, the at least one junction having two alloys based on an antimonide material (Ga₁₋ₓAlₓAs_{y}Sb_{1-y}) lattice-matched on the substrate GaSb. If there are several junctions, two neighbouring junctions are separated by a tunnel junction.

The present invention relates to a photovoltaic cell. A particularly beneficial application thereof is found in applications under high solar concentration. However, it has a broader scope, since it can be used equally well without solar concentration.

In a global context of reduction in greenhouse gas emissions, involving less use of fossil energy for power production, many countries have committed to increasing the share of renewable energy. Taking account of the global economic downturn, there is a twofold challenge: to develop energy production or conversion systems that are both principled from an environmental point of view and economically competitive with respect to systems based on fossil energy. This objective cannot be achieved without a reduction in the cost of production of energy from renewable origin, which requires in some cases an increase in the efficiency of the current conversion systems.

It has been demonstrated that in order to reduce the cost of electricity of solar origin, several solutions can be envisaged:
a. reduction in the costs of production of the existing technologies for a given conversion efficiency. In this field, especially with the first-generation silicon technologies, the room for manoeuvre is quite limited today, since the arrival en masse of new industrial players in the photovoltaic market during the last few years has made it possible to reduce the price of Si cells sixfold in 3 years, thus the price of photovoltaic electricity installations with this type of technology is today 1 euro/cW.
b.—increasing the conversion efficiencies of the cells: This option cannot be used with the first-generation silicon technologies, since these cells have almost reached their thermodynamic limits and the room for improvement with this type of cells is today marginal, which is not the case with the multi-junction cells, known as 3rd-generation, the theoretical potential of which in terms of efficiency is almost infinite, this advantage being further accentuated by use under solar concentration. The photovoltaic sector for very high concentrations relates to systems in which the solar flux has been concentrated by optical systems making it possible to obtain solar irradiance levels greater than 1000 times the irradiance before concentration.
c. Use of optical systems making it possible to concentrate the solar flux: a concentrated photovoltaic (CPV) conversion system can be produced simply by placing a solar cell at the focus of an optical concentrator. As the short-circuit current (Isc) of the cell is directly proportional to the solar flux absorbed, the surface area of the cell necessary for producing a given quantity of electricity can then be reduced by a factor equal to the solar radiation concentration factor (X). In addition, the open circuit voltage (Voc) theoretically increases as Ln(X) when the cell is exposed to the concentrated solar radiation, which provides an equivalent gain in terms of conversion efficiency. In practice, however, the relative gain rarely exceeds 25% for a typical concentration factor of several hundred suns as the series resistance of the cell also causes joule losses that increase with the square of the current, therefore proportionally to the square of X. In addition, the efficiency gain, linked to the increase in Voc, is partially cancelled out by the loss of solar power received, linked to the optical efficiency of the concentrator which also reduces for very high concentrations. Furthermore, the economy achieved on the cells must not be less than the increased cost of the solar concentration and tracking systems. Nevertheless, the use of concentrators is today the only technological option making it possible to use 3rd generation cells based on III-V elements for terrestrial applications.

Even in the 1990s, silicon-based cells were used in concentrators but the potential of this sector is very limited for concentration, as a result in particular of the intrinsically inadequate performance of this type of cells and the significant drop in their efficiency with an increase in their temperature. This is why the 1st generation cells are not employed for a use under concentration, in favour of the III-V sector which is much more promising, at least in the field of high solar concentrations.

A GaInP/GaAs/GaInNAs triple junction cell of 0.3 cm² is known, from the American company Solar Junction® with an efficiency of 44% measured for a concentration ratio of 942X (direct irradiance of 942 kW/m²).

Document WO2012149022 is known, describing a GaInP2/GaAs/Ge triple junction cell in a high concentration system with solar tracking.

A GaInAs/GaAs/GaInP triple junction cell on silicon is known, with an efficiency of 44.4% measured for a concentration factor of 302X. http://sharp-world.com/corporate/news/130614.html

The present invention relates to a photovoltaic cell having a high conversion efficiency at high concentration.

The invention also relates to a cell suitable for absorbing a wide solar spectrum.

The invention further relates to a reduction in the cost of production of electricity of photovoltaic origin under high and very high concentration with respect to the state of the prior art.

At least one of the above objectives is achieved with a photovoltaic cell that can be used under high solar concentration with an optimum efficiency. The cell according to the invention consists of a cell comprising at least one junction produced on a substrate based on gallium antimonide (GaSb), said at least one junction based on lattice-matched antimonide alloy being produced on the substrate.

By high solar concentration is meant a solar irradiance of the sun multiplied by a number greater than or equal to 1000, or even greater than or equal to 900. Thermophotovoltaic (TPV) devices are known in the state of the art. The principle of these devices is the production of electricity from the infrared radiation of a black body under the effect of heat. Such devices are designed for converting the temperature increase of an absorber (black body) into electricity, whether this temperature increase is of solar origin or not. TPV devices require the use of a black body the role of which is to convert the temperature increase into infrared radiation, which is not the case in the present invention, the principle of which is precisely to avoid all heating. In addition, TPV devices have a generally simple architecture and low cost technologies taking account of the low conversion efficiencies obtained.

With the cell according to the invention, the potential of the III-Sb sector is exploited in particular. The substrate is generally GaSb. The cell is preferably produced by epitaxial growth using molecular beam epitaxy (MBE) or metalorganic vapour phase epitaxy (MOCVD) so as to obtain a monolithic cell. The use of antimonide materials (III-SB) makes it possible to achieve a very high efficiency during use under high solar concentration.

Producing several junctions on the substrate makes it possible to cover a broad spectrum of solar flux. Ideally, the photovoltaic cell is a multi-junction cell (at least two junctions) without limitation of the number of junctions. The different junctions are preferably stacks produced by epitaxial growth.

Due to the very good complementarity of the band gaps of the antimonide materials, the cell according to the invention constitutes a very promising and innovative solution for use under highly concentrated solar flux. In fact, the very great variety of accessible band gaps, as a result of the use of alloys that are all lattice-matched on the GaSb substrate, makes it possible to envisage an optimal use of the solar spectrum with a minimum number of junctions. According to an advantageous characteristic of the invention, in the case of several junctions, two adjacent junctions can be separated by a tunnel junction, and the junctions can be constituted by alloys of the same nature and of different compositions, all lattice-matched, on the GaSb substrate.

According to an advantageous characteristic of the invention, said at least one junction can have a band gap energy gradient.

Advantageously, the antimonide alloy is a quaternary material. Other types of material, such as ternary or quinary, can be envisaged.

Advantageously, each alloy can be a Ga₁₋ₓAlₓAs_{y}Sb_{1-y} quaternary antimonide material.

According to a preferred embodiment of the invention, the cell can effectively comprise three junctions:

a first junction based on two materials, each composed of gallium antimonide and respectively n-doped and p-doped,

a second junction based on two materials, respectively n-doped and p-doped, each being a quaternary alloy comprising antimony.

a third junction based on two materials, respectively n-doped and p-doped, each being a quaternary alloy comprising antimony.

Preferably, the quaternary alloy is a Ga₁₋ₓAlₓAs_{y}Sb_{1-y} material, preferably with x comprised between 0 and 1, y=(0.0396·x)/(0.0446+0.0315·x).

This material according to the invention is advantageously designed by epitaxy (by molecular jet or organometallic vapour phase) by varying x and adjusting y, i.e. the arsenic composition so as to preserve the lattice-matching for all quaternary materials according to the invention. X varies with the band gap energy level of the material, and y varies with the lattice parameter of the material.

During the design of the material by epitaxial growth, the composition of the constituent elements of the material is varied (in particular varying the parameters x and y in the example of a quaternary material such as described above) continuously or in steps, so as to obtain not a single band gap energy, but a continuous or stepped variation of the band gap energy for a predetermined junction. For example, the closer to the substrate, the greater the reduction of the band gap energy is. The band gap energy gradient is advantageously produced in this way.

The first junction is advantageously produced directly on the substrate.

Complementary, notably to the foregoing, an arrangement can be envisaged in which the band gap energy level of the first junction is equal to around 0.726 eV, the band gap energy level of the second junction is equal to around 1.22 eV, and the band gap energy level of the third junction is equal to around 1.6 eV. Thus benefit is derived from the complementary nature of the energy levels.

More specifically, and by way of non-limitative example, the alloy of the third junction can be the Al_{0.9}Ga_{0.1}As_{0.085}Sb_{0.95} material. Similarly, the alloy of the second junction can be the Al_{0.4}Ga_{0.6}As_{0.035}Sb_{0.965} material. These alloys are designed so as to maximize the efficiency under high solar concentration.

According to an advantageous characteristic of the invention, the tunnel junctions are produced from InAs/GaSb with doping comprised between 1.10¹⁹ cm⁻³ and 10.10¹⁹ cm⁻³, preferably at 1.10¹⁹ cm⁻³. For example, the total thickness can be around 30 nm.

Moreover, each junction can be doped between 1.10¹⁶ cm⁻³ and 10.10¹⁶ cm⁻³ for the n-type absorbers, preferably at 5.10¹⁶ cm⁻³, and between 1.10¹⁸ cm⁻³ and 10.10¹⁸ cm⁻³ for the p-type emitters, preferably at 5.10¹⁸ cm⁻³.

By way of non-limitative example, the cell according to the invention can have the following dimensional characteristics:

the substrate has a thickness of 350 μm;

the first junction (bottom junction) produced from GaSb has a thickness of 4 μm for the n-type material and 0.2 μm for the p-type material.

the second junction (middle junction) has a thickness of 4 μm for the n-type material and 0.4 μm for the p-type material.

the third junction (top junction) has a thickness of 3 μm for the n-type material and 0.55 μm for the p-type material.

The tunnel junctions can each have a thickness of 15 nm per p-type or n-type material.

Advantageously, each tunnel junction is a diode the n-type material of which has greater doping than that of the directly adjacent n-type alloy. And each tunnel junction is a diode the p-type material of which has greater doping than that of the directly adjacent p-type alloy.

Other advantages and characteristics of the invention will become apparent on examination of the detailed description of an embodiment which is in no way limitative, and the attached drawings, in which:

FIG. 1 is a very simplified diagrammatic view of a photovoltaic conversion device under high solar concentration;

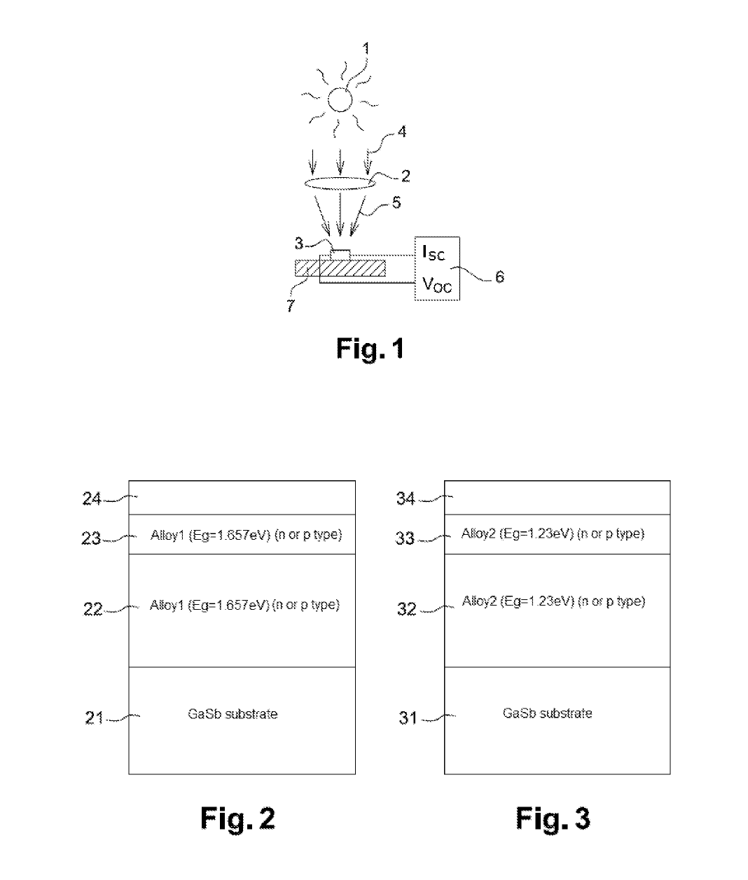

FIG. 2 is a diagrammatic view of a quaternary cell with large band gaps according to the invention;

FIG. 3 is a diagrammatic view of a quaternary cell with an intermediate band gap according to the invention;

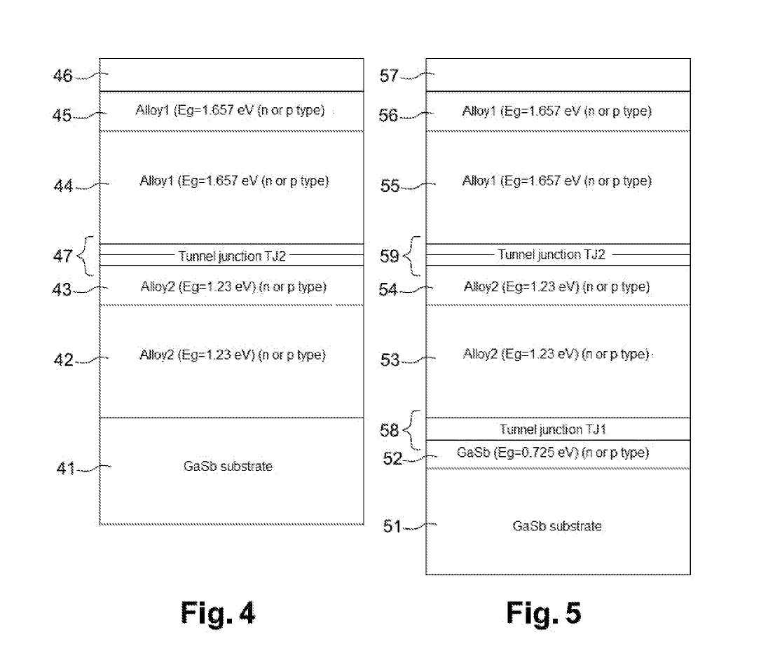

FIG. 4 is a diagrammatic view of a tandem quaternary cell (two junctions) according to the invention;

FIG. 5 is a diagrammatic view of a triple-junction quaternary cell according to the invention;

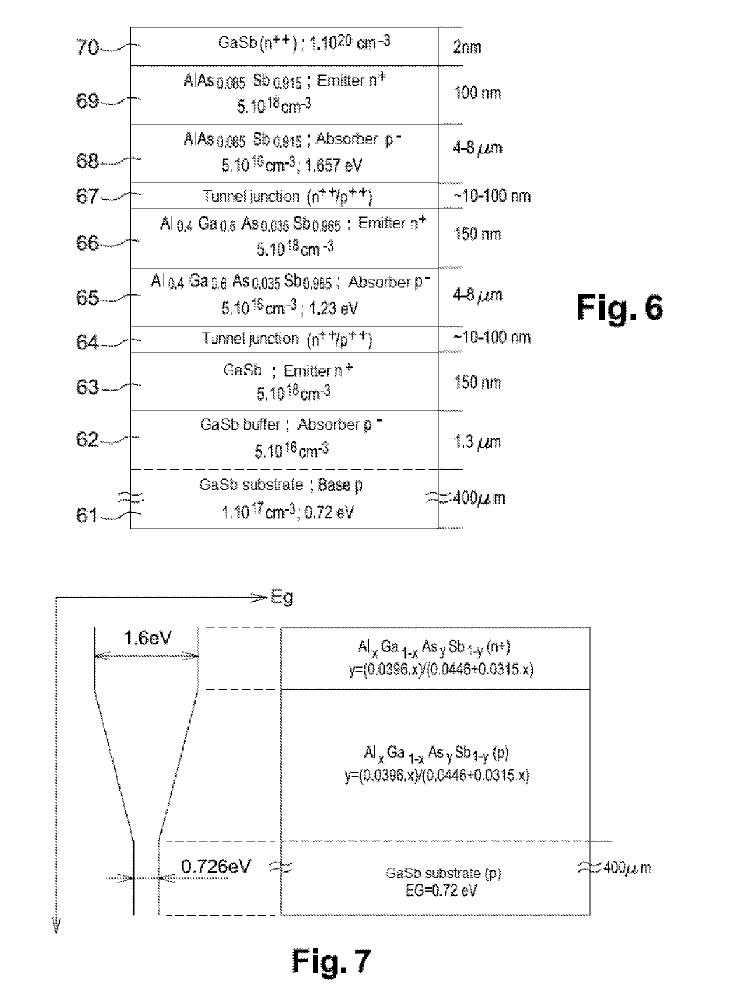

FIG. 6 is a diagrammatic view of an optimized triple-junction quaternary cell according to the invention; and

FIG. 7 is a diagrammatic view of a junction with band gap energy gradient.

The cell according to the present invention opens up a new technological route in that it consists of a multi-junction cell based on antimonide materials (GaSb, GaAlAsSb, etc.) manufactured monolithically by molecular beam epitaxy (MBE). Due to the very good complementarity of the band gaps of the materials (0.725 eV for GaSb, up to 1.64 eV for the band gap of the quaternary GaAlAsSb (indirect band gap) and 2 eV (indirect band gap)) lattice-matched on GaSb, such a cell constitutes a credible and original alternative to the existing cells for use under highly concentrated solar flux.

According to the invention, the alloys used make it possible to adjust the band gap and the lattice parameter of the materials independently.

Implementing such a solar flux involves optical concentration systems. Two major concentrator technologies are currently used for concentrator photovoltaic conversion: reflection systems, using parabolic concentrators, and refraction systems, based on Fresnel lenses. With parabolic concentrators, very high concentration ratios can be achieved (X>10000), while Fresnel lenses are scarcely able to exceed a factor of 1000 to 1500. In both cases, the use of a solar tracker system is required. Other concepts such as luminescent concentrators would make it possible to dispense with a tracker, but their performance is today still mediocre.

The cell according to the present invention can be incorporated into solar panels associated with any type of concentrator photovoltaic system. By way of non-limitative example, the cell according to the invention can advantageously be used in a photovoltaic system such as that described in document WO2012/149022. This document WO2012/149022 describes a solar tracking system for a concentrator photovoltaic device. The cell according to the invention can be used instead of the triple-junction cells described in this document WO2012/149022, namely an alloy comprising indium-gallium phosphide, gallium arsenide and germanium GaInP. The cell of the prior art allows a solar conversion frequency range extending from the near ultraviolet spectrum at 350 nm to the near infrared spectrum at around 1600 nm.

The principle of solar concentration is shown in FIG. 1. The sun 1 illuminates a concentrator 2. The solar flux 4 that reaches the concentrator 2 is converted into a concentrated flux 5 which is guided to a photovoltaic cell 3 placed on a cooling device 7. A measuring unit 6 makes it possible to recover a short-circuit current Isc and an open circuit voltage Voc. The electric current produced by the cell 3 is proportional to the luminous flux that it receives. By concentrating the solar flux on the cell X times using the concentrator 2 (parabolic concentrator or Fresnel lens), an electric current is obtained that is X times greater than the current obtained without concentration.

In industrial concentrator photovoltaic systems, a two-stage concentration optics can be used: as well as the primary concentrator (parabola or lens), a secondary optics is generally added to the focus which optionally provides a function of overconcentration, but especially of homogenization of the luminous flux that is essential in order to avoid a degradation of the performance of the solar cell. For concentration values of several hundred suns (or even up to 1000 or even beyond for a cell with small dimensions) passive cooling (cell linked to a heat sink cooled by natural convection) is generally sufficient to limit overheating of the cell. At the highest concentrations, active cooling (forced convection) using a heat transfer fluid (water) becomes essential.

FIG. 2 shows an example of a photovoltaic cell according to the invention. A substrate 21 of GaSb material on which a first layer 22 has been grown by epitaxia is shown, having a band gap energy equal to 1.657 eV. This layer 22 can be n-doped or p-doped. Then a second layer 23 is produced on the first layer 22, but having a smaller thickness. The layers 22 and 23 are produced based on one and the same antimonide material, i.e. one and the same alloy called alloy1, and thus both having a band gap energy equal to 1.657 eV. The second layer 23 is p-doped or n-doped. Advantageously, alloy1 is an antimony-based quaternary material so that a perfect lattice match is produced on the GaSb substrate 21. The cell is finished with a termination layer 24.

FIG. 3 shows a GaSb substrate 31 on which a first layer 32 is produced by epitaxial growth, having a band gap energy equal to 1.23 eV. This layer 22 can be n-doped or p-doped. Then a second layer 33 is produced on this first layer 32, but having a smaller thickness. The layers 32 and 33 are produced based on one and the same antimonide material, i.e. one and the same alloy called alloy2, and thus both have a band gap energy equal to 1.23 eV. The second layer 33 is p-doped or n-doped. Advantageously, alloy2 is an antimony-based quaternary material so that a perfect lattice match is produced on the GaSb substrate 31. The cell is finished with a termination layer 34.

The energy levels are data that may be approximate. For example the band gap energy of alloy2 is 1.23 eV but can equally well be 1.22 eV.

The band gap energy of the GaSb is 0.726 eV. The cells in FIGS. 2 and 3 make it possible to capture the solar flux over an extended spectrum due to the fact that the band gap energies are complementary.

In order to extend this spectrum further, it is envisaged to produce several junctions as shown in FIGS. 4 and 5.

FIG. 4 shows a GaSb substrate 41 on which a first layer 42 of alloy2 is produced by epitaxial growth, having a band gap energy equal to 1.23 eV. This layer 42 can be n-doped or p-doped. Then a second layer 43 of alloy2 is produced on the first layer 42, but having a smaller thickness. The layer 43 is p-doped or n-doped. The assembly of the two layers 42 and 43 constitutes a first junction. Then a second junction is produced, constituted by the layers 44 and 45 of alloy1. The layer 44 is n-doped or p-doped. The layer 45 produced directly on the layer 44 is p-doped or n-doped. The cell is finished with a termination layer 46. Advantageously, a tunnel junction 47 is produced between the two junctions by epitaxial growth, the benefit of which is the extraction of the carriers originating from the first junction to the contact (termination layer 46) of the cell.

FIG. 5 ideally contains three junctions produced on the GaSb substrate 51. The first junction advantageously comprises a first layer constituted by the substrate 51 on which a second n- or p-doped layer 52 of GaSb is produced. A tunnel junction 58 makes it possible to extract the carriers originating from the GsSb junction to the second junction. Then the second junction is grown, composed of the layer 53 of alloy2 and the layer 54 of alloy2. In general, in the cells described, the second layer (the upper layer) has a smaller thickness than the first layer. However, other arrangements are possible, such as a junction in which the upper layer is of a greater thickness than the lower layer, independently of the arrangement of the other junctions.

A second tunnel junction 59 is produced on the second junction 53, 54 so as to grow a third junction 55, 56 composed of the layer 55 of alloy1 surmounted by the layer 56 also of alloy1.

The two tunnel junctions allow a band connection between the different junctions, so as to obtain effective absorption of the solar flux spectrum. The cell is finished with a termination layer 57.

Reference will now be made to FIG. 6, a preferential, non-limitative example of a photovoltaic cell according to the invention. This is a cell based on antimonide materials having a very good complementarity of the band gaps with only three junctions, all lattice-matched on a GsSb substrate 61. Advantageously, the substrate is n-doped with a concentration of 1·10¹⁷ cm⁻³ and a band gap energy of 0.726 eV. Its thickness is around 400 μm.

Then a buffer layer 62 is produced from p-doped GaSb material with a concentration of 5·10¹⁶ cm⁻³. Its thickness is 1.3 μm. This layer 62 is associated with a layer 63, which together form a first junction. The layer 63 of GaSb material is n+-doped with a concentration of 5·10¹⁸ cm⁻³. Its thickness is 150 nm. This layer has a much smaller thickness, practically with a ratio of one to ten, compared with the thickness of the layer 62. In the pair 62, 63 forming the p-n junction, the layer 62 has an absorber role, while on the other hand the layer 63 has an emitter role.

A second junction 65, 66 can be distinguished, composed of a layer 65 of antimonide material, more specifically a quaternary alloy of composition Al_{0.4}Ga_{0.6}As_{0.035}Sb_{0.965}. This layer 65 is p-doped with a concentration of 5·10¹⁶ cm⁻³. Its thickness is 4 to 8 μm. This layer 65 is associated with a layer 66, which together form the second junction.

The layer 66 of antimonide material, more specifically a quaternary alloy also of composition Al_{0.4}Ga_{0.6}As_{0.035}Sb_{0.965} is n+-doped with a concentration of 5·10¹⁸ cm⁻³. Its thickness is 150 nm. This layer has a much smaller thickness compared with the thickness of the layer 65. In the pair 65, 66 forming the p-n junction, the layer 65 has an absorber role, while on the other hand the layer 66 has an emitter role. The two layers each have a band gap energy of 1.23 eV.

Between the two junctions 62, 63 and 65, 66 a tunnel junction 64 is produced that is in fact a diode constituted by a first layer which can be produced from p++-doped InAsGaSb with a concentration of 1·10¹⁹ cm⁻³, and a second n++-doped layer with a concentration of 1·10¹⁹ cm⁻³. The thickness of the tunnel junction 64 is comprised between 10 and 100 nm.

Several types of alloy can be used for the tunnel junctions according to the invention such as for example:

InAs

GaSb

GaₓIn₁₋ₓAs

GaₓIn₁₋ₓSb

GaAs₁₋ₓSbₓ

AlₓGa₁₋ₓAs

InAs₁₋ₓSbₓ

GaₓIn₁₋ₓAs_{y}Sb_{1-y}

AlₓGa₁₋ₓAs_{y}Sb_{1-y}

The tunnel junctions according to the invention can be characterized in particular by high doping (from 1·10¹⁹ cm⁻³), a thickness of the order of 30 nm (between 10 and 100 nm) and constituted by one of the materials mentioned above.

Thus it is possible to determine the level of band gap energy of each junction over a continuous range of energy values, for example starting from the energy level of the band gap of the substrate. In the case in point this range can run continuously from the energy level of the GaSb substrate band gap (725 meV) to 1.64 eV, which is not the case with the GaInP/GaInAs sector preferred in the state of the prior art. The energy levels are thus determined so as to ensure continuity of absorption of the solar flux. In other words, the quaternary alloy can have a band gap energy comprised between 0.725 eV and 1.64 eV with a direct band gap (2 eV with an indirect band gap).

A third junction 68, 69 is produced above the second junction. This third junction is composed of a layer 68 of antimonide material, more specifically a quaternary alloy of composition AlAs_{0.085y}Sb_{0.915}. This layer 68 is p-doped with a concentration of 5·10¹⁶ cm⁻³. Its thickness is 4 to 8 μm. This layer 68 is associated with the layer 69, which together form the third junction.

The layer 69 of antimonide material, more specifically a quaternary alloy also of composition AlAs_{0.085y}Sb_{0.915}is n-doped with a concentration of 5·10¹⁸ cm⁻³. Its thickness is 100 nm. This layer has a much smaller thickness compared with the thickness of the layer 68. In the pair 68, 69 forming the p-n junction, the layer 68 has an absorber role, while on the other hand the layer 69 has an emitter role.

Between the two junctions 65, 66 and 68, 69 a tunnel junction is produced that is in fact a diode constituted by a first p++-doped layer with a concentration of 1·10¹⁹ cm⁻³, and a second n++-doped layer with a concentration of 1·10¹⁹ cm⁻³. The thickness of the tunnel junction 67 is comprised between 10 and 100 nm.

A last contact layer 70 is arranged on the third junction. It is constituted by a material based on n++-doped GaSb at n++à1·10²⁰ cm⁻³. Its thickness is around 2 nm.

FIG. 7 shows an example of a cell comprising a single junction (other junctions of the same type or not can be added) having a variable band gap

energy Eg. The “energy funnel” shown in the p-doped area is a simple illustration of the variation in the band gap energy Eg inside the cell.

Thus, the present invention relates to a multi-junction solar cell with a very high efficiency optimized for use under high solar concentrations (>1000×). It is constituted by antimonide-based materials (GaSb, Ga₁₋ₓAlₓAs_{y}Sb_{1-y}, etc.) obtained in the form of a monolithic stack, preferentially by molecular beam epitaxia (MBE). The use of antimonide materials that are all lattice-matched quaternary alloys on the substrate makes it possible to obtain a very good complementarity of the band gaps between these materials.

The alloys used make it possible to vary the band gap continuously between 725 meV and over 2 eV while remaining lattice-matched on the GaSb substrate. The GaInP/GaAs or Ge sectors do not allow the band gap and the lattice parameter of the materials to be adjusted independently, which does not make it possible to obtain all the band gaps required for optimal use of the solar spectrum, in particular for band gap energies less than 1.45 eV.

Of course, the invention is not limited to the examples which have just been described and numerous adjustments can be made to these examples without exceeding the scope of the invention, in particular the number of junctions and the composition of the alloys used. The example in FIG. 6 is based on a p-type substrate, but a cell could also be envisaged based on an n-type substrate.

1. A photovoltaic cell that can be used under a high solar concentration, comprising: a cell comprising at least one junction produced on a substrate based on gallium antimonide GaSb, said at least one junction being produced on the substrate based on lattice-matched antimonide alloy.

2. The photovoltaic cell according to claim 1, characterized in that in the case of several junctions, two adjacent junctions are separated by a tunnel junction, and in that the junctions are constituted by alloys of the same nature and of different compositions, all lattice-matched, on the GaSb substrate.

3. The photovoltaic cell according to claim 1, characterized in that said at least one junction has a band gap energy gradient.

4. The photovoltaic cell according to claim 1, characterized in that the antimonide alloy is a quaternary material.

5. The photovoltaic cell according to claim 4, characterized in that the quaternary alloy is a Ga₁₋ₓAlₓAs_{y}Sb_{1-y} material.

6. The photovoltaic cell according to claim 5, characterized in that the Ga₁₋ₓAlₓAs_{y}Sb_{1-y} material is such that x is comprised between 0 and 1, and y=(0.0396·x)/(0.0446+0.0315·x).

7. The photovoltaic according to claim 1, characterized in that it comprises three junctions:
a first junction based on two materials, each composed of gallium antimonide and respectively n-doped and p-doped;
a second junction based on two materials, respectively n-doped and p-doped, each being a quaternary alloy comprising antimony; and
a third junction based on two materials, respectively n-doped and p-doped, each being a quaternary alloy comprising antimony.

8. The photovoltaic cell according to claim 4, characterized in that the quaternary alloy has a band gap energy comprised between 0.725 eV and 1.64 eV with a direct band gap or 2 eV with an indirect band gap.

9. The photovoltaic cell according to claim 7, characterized in that the band gap energy of the first junction is equal to around 0.726 eV; the band gap energy of the second junction is equal to around 1.2 eV; and the band gap energy of the third junction is equal to around 1.6 eV.

10. The photovoltaic cell according to claim 7, characterized in that the alloy of the third junction is the material AlAs_{0.085}Sb_{0.915}.

11. The photovoltaic cell according to claim 7, characterized in that the alloy of the second junction is the material Al_{0.4}Ga_{0.6}As_{0.035}Sb_{0.965}.

12. The photovoltaic cell according to claim 1, characterized in that the tunnel junctions are produced based on InAs/GaSb and are doped between 1·10¹⁹ cm⁻³ and 10·10¹⁹ cm⁻³, preferably at 1·10¹⁹ cm⁻³.

13. The photovoltaic cell according to claim 1, characterized in that each junction is doped between 1·10¹⁶ cm⁻³ and 10·10¹⁶ cm⁻³ for the n-type absorbers, preferably at 5·10¹⁶ cm⁻³ , and between 1·10¹⁸ cm⁻³ and 10·10¹⁸ cm⁻³ for the p-type emitters, preferably at 5·10¹⁸ cm⁻³.

14. The photovoltaic cell according to claim 7:
the substrate is of p type and has a thickness of several hundreds of μm;
the first junction has a thickness comprised between 1 μm and 2 μm for the p-type material and 150 nm for the n-type material;
the second junction has a thickness comprised between 4 μm and 8 μm for the p-type material and 150 nm for the n-type material; and
the third junction has a thickness comprised between 4 μm and 8 μm for the p-type material and 100 nm for the n-type material.

15. The photovoltaic cell according to claim 7, characterized in that the tunnel junctions each have a thickness of 15 nm for p-type or n-type material.

16. The photovoltaic cell according to claim 1, characterized in that each tunnel junction is a diode the n-type material of which has a higher doping than the doping of the directly adjacent n-type alloy.

17. The photovoltaic cell according to claim 1, characterized in that each tunnel junction is a diode the p-type material of which has a higher doping than the doping of the directly adjacent p-type alloy.
